(19) United States
(12) Patent Application Publication
(10) Pub. No.: US 2026/0068131 A1
(43) Pub. Date: Mar. 5, 2026

(54) SEMICONDUCTOR STRUCTURE AND METHOD OF FORMING THE SAME

(71) Applicant: NANYA TECHNOLOGY CORPORATION, New Taipei City (TW)

(72) Inventor: Jhen-Yu TSAI, New Taipei City (TW)

(21) Appl. No.: 18/823,639

(22) Filed: Sep. 3, 2024

(51) Int. Cl. H10B 12/00

(52) U.S. Cl. CPC H10B 12/34; H10B 12/053

(57) ABSTRACT

The present disclosure provides a semiconductor structure. The semiconductor structure includes a substrate, a first word line, and a first contact structure. The first word line extends along a first direction on the substrate, in which the first word line includes a first end portion, a second end portion, and a first middle portion. The first middle portion is between the first end portion and the second end portion, in which a top surface of the first end portion and a top surface of the second end portion are lower than a top surface of the first middle portion, and a length of the second end portion is larger than a length of the first end portion. The first contact structure is on the first end portion of the first word line.

### BACKGROUND

### Field of Invention

The present disclosure relates to a semiconductor structure and a method of forming the same.

### Description of Related Art

Word lines are used widely in a semiconductor structure, such as a dynamic random-access memory (DRAM) device. However, as the semiconductor structure is fabricated smaller, the distance between the adjacent word lines becomes smaller, which leads to a stronger coupling between the adjacent word lines. Once the distance between the adjacent word lines is too small, the coupling may be too large to perish the performance of the semiconductor structure, for example, increasing the signal interference between the adjacent word lines. In addition, the end portions of the word line usually have larger stress to make the word line bend easily. When the distance between the adjacent word lines is fabricated smaller and when the word lines bend because of the stress, the distance between the adjacent word lines may be smaller than expected to cause the coupling problem. Therefore, it is necessary to develop a novel semiconductor structure including the improved word line and a novel method of forming the same.

### SUMMARY

The present disclosure provides a semiconductor structure. The semiconductor structure includes a substrate, a first word line, and a first contact structure. The first word line extends along a first direction on the substrate, in which the first word line includes a first end portion, a second end portion, and a first middle portion. The first middle portion is between the first end portion and the second end portion, in which a top surface of the first end portion and a top surface of the second end portion are lower than a top surface of the first middle portion, and a length of the second end portion is larger than a length of the first end portion. The first contact structure is on the first end portion of the first word line.

In some embodiments, a horizontal distance from a boundary of the first end portion closest to the second end portion to the first contact structure is from 100 nm to 1000 nm.

In some embodiments, the first middle portion includes a high work function layer and a low work function layer disposed on the high work function layer, a work function of the high work function layer is larger than a work function of the low work function layer, the first end portion is a work function layer having a work function larger than the work function of the low work function layer, and the second end portion is a work function layer having a work function larger than the work function of the low work function layer.

In some embodiments, the first middle portion includes a metal-containing layer and a silicon-containing conductive layer disposed on the metal-containing layer, the first end portion includes a metal-containing layer in direct contact with the first contact structure, and the second end portion includes a metal-containing layer.

In some embodiments, a first top surface of the substrate around the first middle portion is higher than a second top surface of the substrate around the first end portion and a third top surface of the substrate around the second end portion.

In some embodiments, the semiconductor structure further includes a second word line and a second contact structure. The second word line is adjacent to the first word line and extends along the first direction on the substrate, in which the second word line includes a third end portion, a fourth end portion, and a second middle portion. The third end portion is adjacent to the first end portion of the first word line. The fourth end portion is adjacent to the second end portion of the first word line. The second middle portion is between the third end portion and the fourth end portion, in which a top surface of the third end portion and a top surface of the fourth end portion are lower than a top surface of the second middle portion, and a length of the third end portion is larger than a length of the fourth end portion. The second contact structure is on the fourth end portion of the second word line.

In some embodiments, a virtual line passes through the first contact structure and a point of the third end portion in a second direction perpendicular to the first direction, and a horizontal distance from a boundary of the third end portion closest to the fourth end portion to the point is from 200 nm to 3000 nm.

In some embodiments, the first word line, the first contact structure, the second word line, and the second contact structure are in a group, the semiconductor structure further includes groups respectively identical to the group on the substrate, and each one of the groups is aligned with the group.

The present disclosure also provides a method of forming a semiconductor structure. The method includes the following operations. A first word line extending along a first direction is formed on a substrate. A mask is formed on a first middle portion of the first word line and exposes a first end and a second end of the first word line, in which a length of the second end exposed by the mask is larger than a length of the first end exposed by the mask, and the first middle portion is between the first end and the second end. A portion of the first end and a portion of the second end of the first word line exposed by the mask are etched to form a first end portion and a second end portion of the first word line respectively, in which a top surface of the first end portion and a top surface of the second end portion are lower than a top surface of the first middle portion. A first contact structure is formed on the first end portion.

In some embodiments, a length of the second end portion is larger than a length of the first end portion.

In some embodiments, the first end includes a high work function layer and a low work function layer disposed on the high work function layer, and a work function of the high work function layer is larger than a work function of the low work function layer; when etching the portion of the first end of the first word line exposed by the mask, the portion includes the low work function layer; and when forming the first contact structure, the first contact structure is in direct contact with the high work function layer.

In some embodiments, etching the portion of the first end of the first word line exposed by the mask further includes etching a portion of the substrate around the first end.

In some embodiments, the method further includes the following operations. A second word line extending along the first direction is formed on the substrate. The mask is formed on a second middle portion of the second word line and exposes a third end and a fourth end of the second word line, in which a length of the third end exposed by the mask is larger than a length of the fourth end exposed by the mask, the second middle portion is between the third end and the fourth end, and the third end and the fourth end are respectively adjacent to the first end and the second end of the first word line. A portion of the third end and a portion of the fourth end of the second word line exposed by the mask are etched to form a third end portion and a fourth end portion of the second word line respectively.

In some embodiments, the method further includes forming a second contact structure on the fourth end portion.

In some embodiments, the mask has jagged edges along the first direction.

### BRIEF DESCRIPTION OF THE DRAWINGS

The present disclosure can be more fully understood by reading the following detailed description of the embodiments, with reference made to the accompanying drawings.

FIG. 1 is a top view of a semiconductor structure according to some embodiments of the present disclosure.

FIG. 2A is a cross-sectional view along a line A-A′ of the semiconductor structure in FIG. 1 according to some embodiments of the present disclosure.

FIG. 2B is a cross-sectional view along a line B-B′ or a line b-b′ of the semiconductor structure in FIG. 1 according to some embodiments of the present disclosure.

FIG. 2C is a cross-sectional view along a line C-C′ or a line c-c′ of the semiconductor structure in FIG. 1 according to some embodiments of the present disclosure.

FIG. 2D is a cross-sectional view along a line D-D′ or a line d-d′ of the semiconductor structure in FIG. 1 according to some embodiments of the present disclosure.

FIG. 3 is a flow chart of a method of forming a semiconductor structure according to some embodiments of the present disclosure.

FIGS. 4A, 5A, 6A, 8A, 9A, and 10A are cross-sectional views of the structures along the line A-A′ as shown in FIG. 1 in forming the semiconductor structure according to some embodiments of the present disclosure.

FIGS. 4B, 5B, 6B, 8B, 9B, and 10B are cross-sectional views of the structures along the line B-B′ or the line b-b′ as shown in FIG. 1 in forming the semiconductor structure according to some embodiments of the present disclosure.

FIGS. 40, 50, 60, 80, 9C, and 10C are cross-sectional views of the structures along the line C-C′ or the line c-c′ as shown in FIG. 1 in forming the semiconductor structure according to some embodiments of the present disclosure.

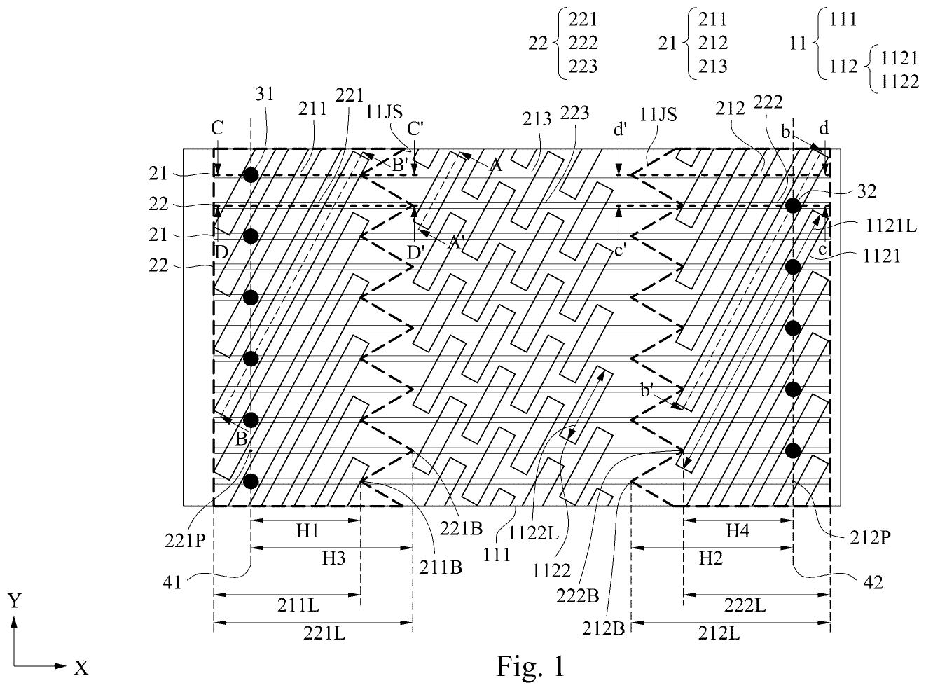

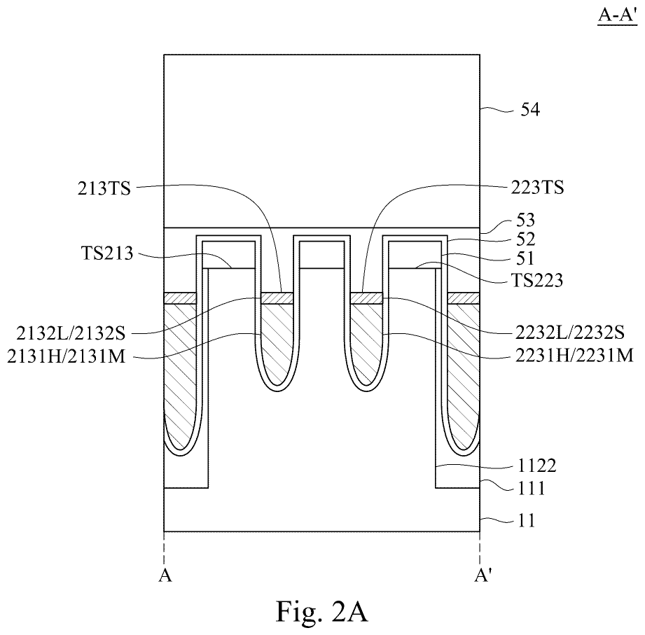

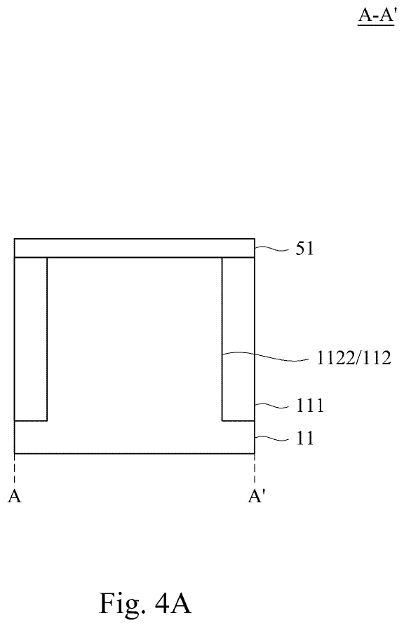

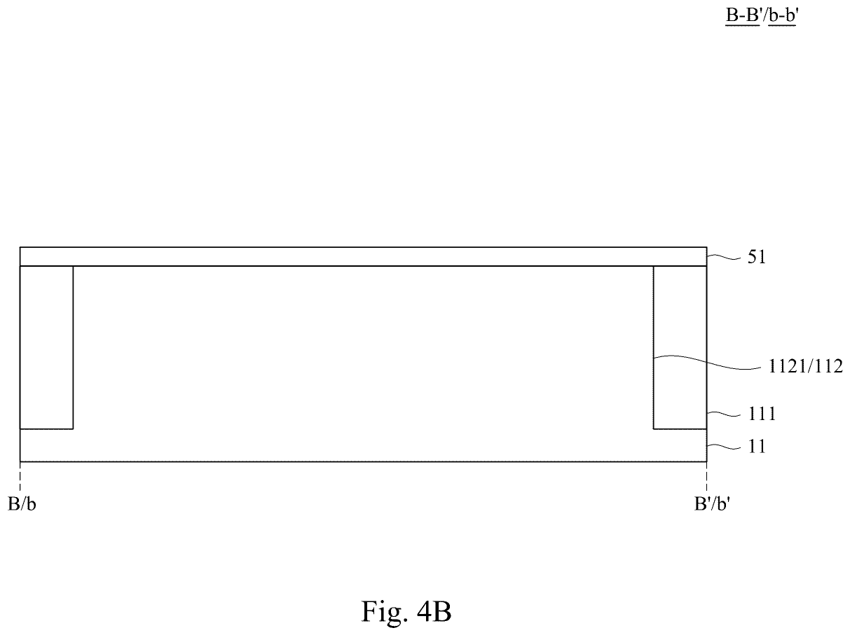

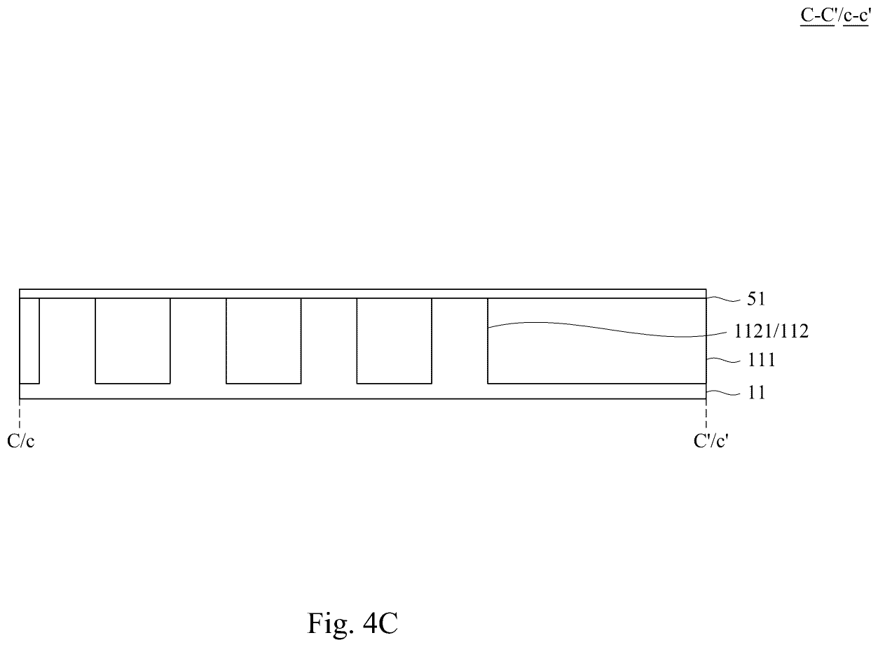

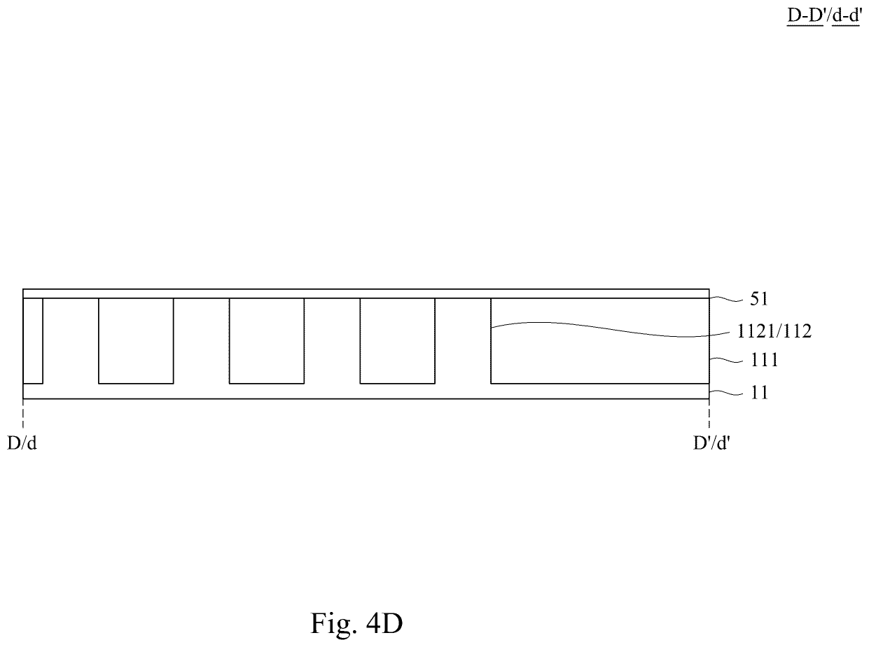

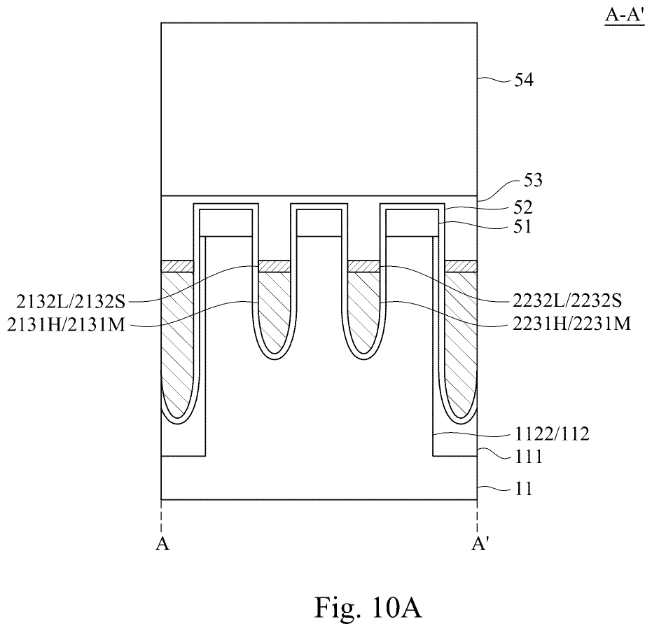

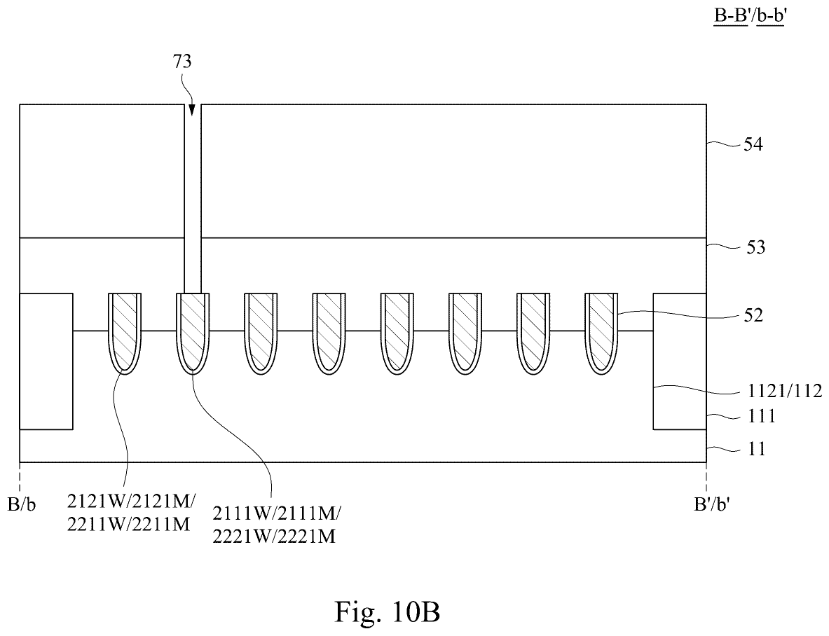

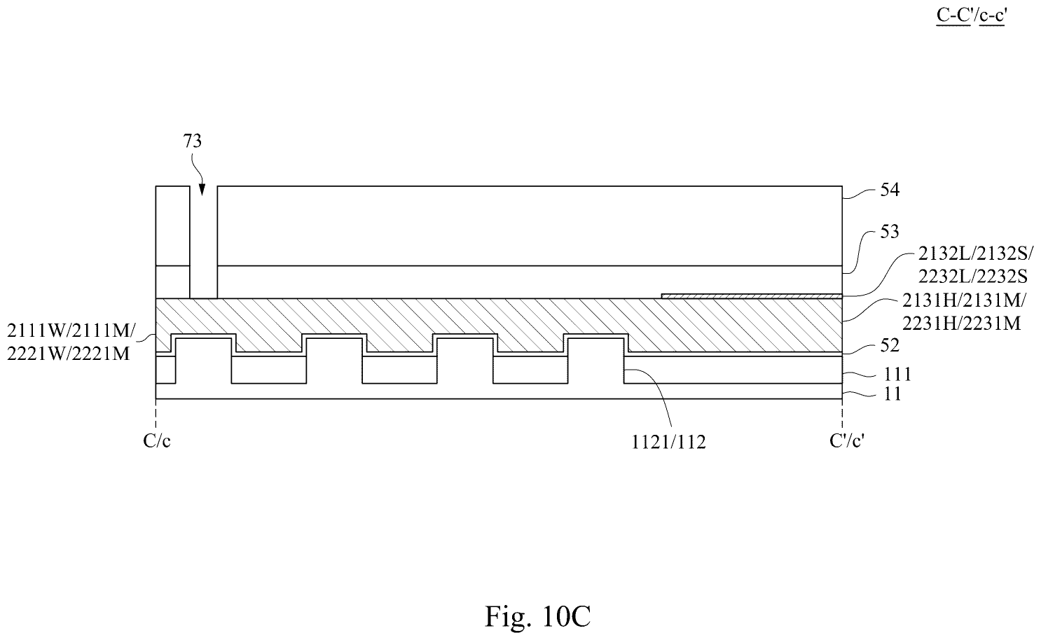

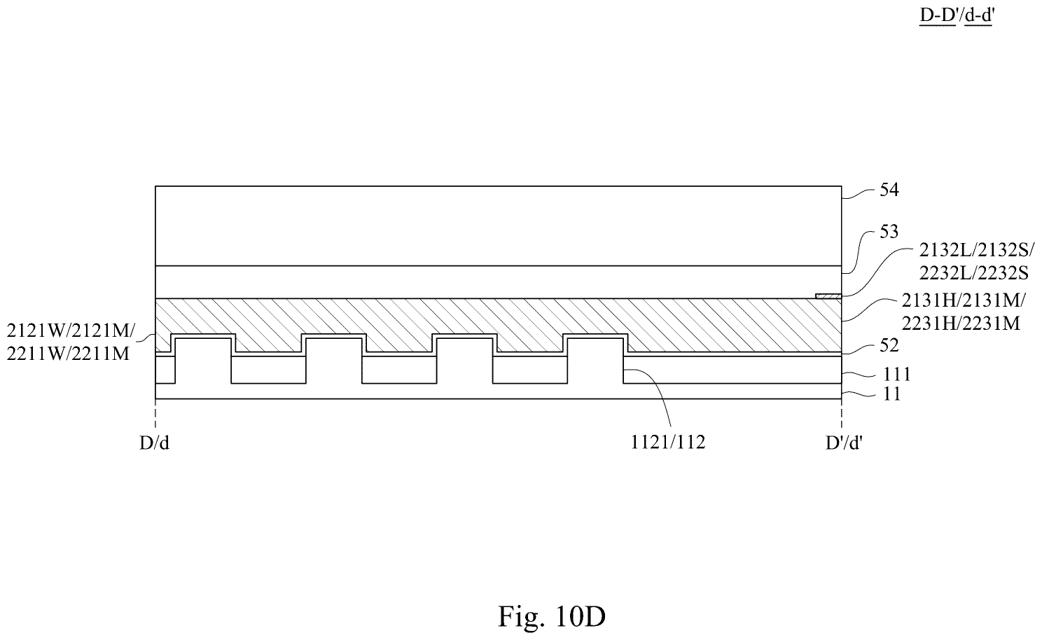

FIGS. 4D, 5D, 6D, 8D, 9D, and 10D are cross-sectional views of the structures along the line D-D′ or the line d-d′ as shown in FIG. 1 in forming the semiconductor structure according to some embodiments of the present disclosure.

FIG. 7 is a top view of the structures in forming the semiconductor structure according to some embodiments of the present disclosure.

### DETAILED DESCRIPTION

To make the description of the present disclosure detailed and complete, the following is an illustrative description of the aspects of the embodiments. This is not to limit the embodiments of the present disclosure to only one form. The embodiments of the present disclosure may be combined or substituted with each other when it is beneficial, and other embodiments may be added without further explanation.

In addition, spatially relative terms, such as below and above, etc., may be used in the present disclosure to describe the relationship between one element (or feature) to another element (or feature) in the figures. In addition to the orientation depicted in the figures, spatially relative terms are intended to encompass different orientations of the device in use or in operation. For example, the device may be oriented otherwise (e.g., rotated 90 degrees), and the spatially relative terms can be interpreted accordingly. In the present disclosure, unless otherwise indicated, the same element numbers in different figures refer to the same or similar elements formed from the same or similar materials by the same or similar methods.

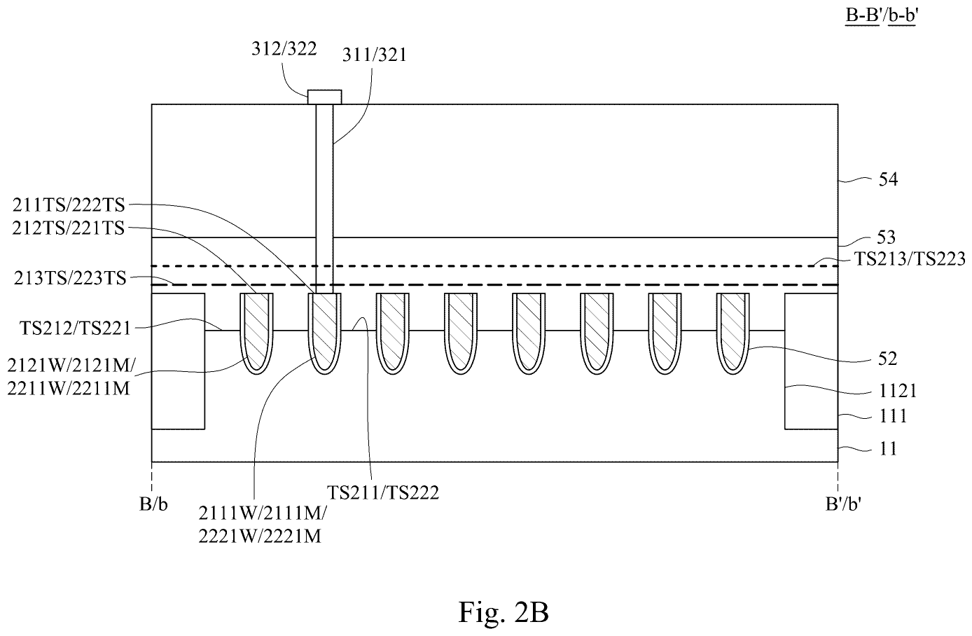

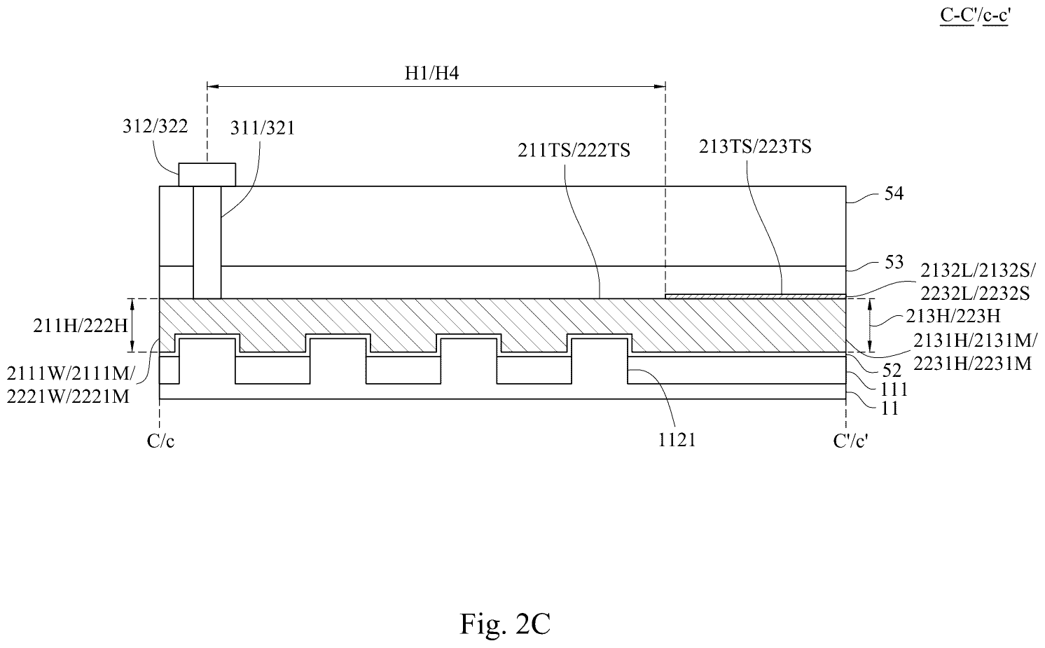

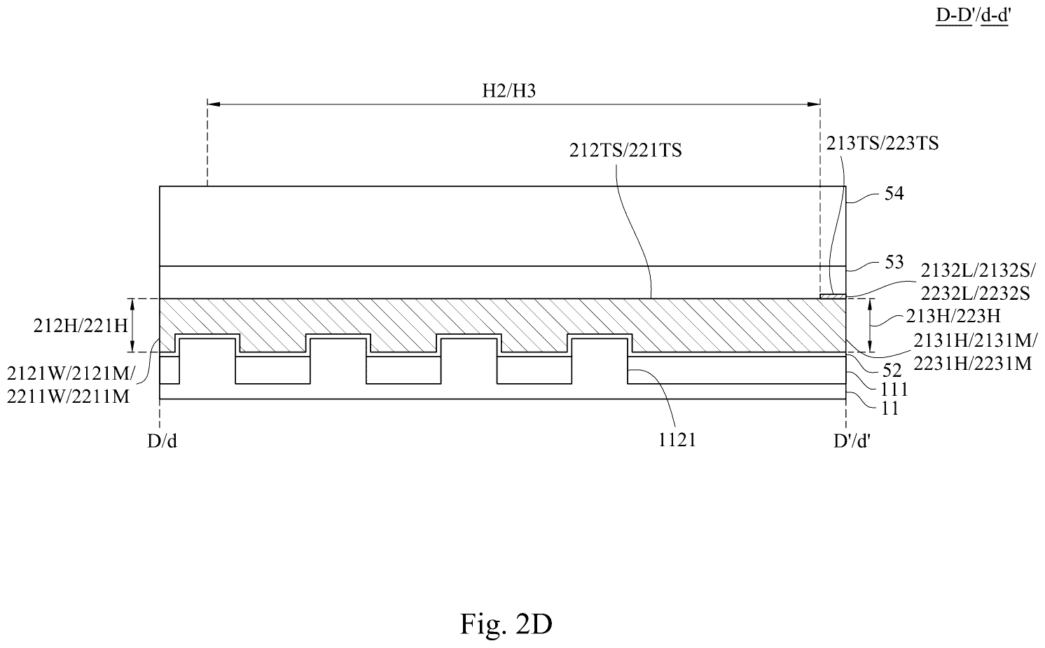

The present disclosure provides a semiconductor structure, as shown in FIGS. 1, 2A, 2B, 2C, and 2D. The semiconductor structure includes a substrate 11, a first word line 21, and a first contact structure 31. The first word line 21 extends along a first direction X on the substrate 11, in which the first word line 21 includes a first end portion 211, a second end portion 212, and a first middle portion 213. The first middle portion 213 is between the first end portion 211 and the second end portion 212, in which a top surface 211TS of the first end portion 211 and a top surface 212TS of the second end portion 212 are lower than a top surface 213TS of the first middle portion 213, and a length 212L of the second end portion 212 is larger than a length 211L of the first end portion 211. The first contact structure 31 is on the first end portion 211 of the first word line 21. The first word line 21 of the present disclosure reduces stress by including the first end portion 211 and the second end portion 212, thereby reducing the first word line 21 to bend. The semiconductor structure of the present disclosure is described in detail with the following embodiments.

In some embodiments, the semiconductor structure further includes a second word line 22 extending along the first direction X on the substrate 11 and a second contact structure 32 disposed on the second word line 22. The second word line 22 is adjacent to the first word line 21. The designs of the second word line 22 and the second contact structure 32 are substantially the same as the first word line 21 and the first contact structure 31, except that the second word line 22 and the second contact structure 32 are the opposite of the first word line 21 and the first contact structure 31 on the substrate 11 along the first direction X. Therefore, to simplify the number of the figures, FIG. 2B can be the cross-sectional view along the line B-B′ or the line b-b′ in FIG. 1, FIG. 2C can be the cross-sectional view along the line C-C′ or the line c-c′ in FIG. 1, and FIG. 2D can be the cross-sectional view along the line D-D′ or the line d-d′ in FIG. 1, as long as the start point and the end point of the cross-sectional line that extends from the start point to the end point are noted when reading the figure. In addition, the line C-C′, the line c-c′, the line D-D′, and the line d-d′ of the present disclosure are along the first direction X.

The second word line 22 includes a third end portion 221, a fourth end portion 222, and a second middle portion 223 between the third end portion 221 and the fourth end portion 222. The third end portion 221 is adjacent to and aligned with the first end portion 211 of the first word line 21. The fourth end portion 222 is adjacent to and aligned with the second end portion 212 of the first word line 21. A top surface 221TS of the third end portion 221 and a top surface 222TS of the fourth end portion 222 are lower than a top surface 223TS of the second middle portion 223, and a length 221L of the third end portion 221 is larger than a length 222L of the fourth end portion 222. The second contact structure 32 is on the fourth end portion 222 of the second word line 22. The second word line 22 reduces stress by including the third end portion 221 and the fourth end portion 222, thereby reducing the second word line 22 to bend. Moreover, since the designs of the second word line 22 and the second contact structure 32 are opposite to the designs of the first word line 21 and the first contact structure 31 in the first direction X on the substrate 11, the stress of first word line 21 and the stress of second word line 22 are reduced when the second word line 22 is disposed beside the first word line 21, thereby preventing the two word lines from bending to become too close to cause an electrical short and/or signal interference. In some embodiments, no contact structure (e.g., the first contact structure 31) extending vertically above the second end portion 212 and contacting the second end portion 212 is disposed on the second end portion 212 of the first word line 21, and no contact structure (e.g., the second contact structure 32) extending vertically above the third end portion 221 and contacting the third end portion 221 is disposed on the third end portion 221 of the second word line 22.

In some embodiments, the numbers of the word lines and the contact structures on the substrate 11 are not limited. For example, the numbers of the first word line 21, the first contact structure 31, the second word line 22, and the second contact structure 32 are plurals respectively on the substrate 11, as shown in FIG. 1, such that the first word line 21 and the first contact structure 31 and the second word line 22 and the second contact structure 32 are arranged repeatedly and alternatively on the substrate 11. When the semiconductor structure includes a plurality of the first word lines 21 and a plurality of the first contact structures 31 respectively disposed on the first word lines 21 and a plurality of the second word lines 22 and a plurality of the second contact structures 32 respectively disposed on the second word lines 22, more components (e.g. the gates of the transistors) can be integrated into the semiconductor structure to increase the performance of the semiconductor structure. In some embodiments, one first word line 21, one first contact structure 31, one second word line 22, and one second contact structure 32 can be regarded as in a group, and the semiconductor structure includes groups respectively identical to this group and aligned with this group on the substrate 11.

Continuously discuss each first word line 21 and each second word line 22. In some embodiments, the first middle portion 213 of the first word line 21 and the second middle portion 223 of the second word line 22 are portions of the word lines including the gates of the transistors, and the word lines are used to control the switches of the gates. In addition, the first end portion 211 and the second end portion 212 of the first word line 21 and the third end portion 221 and the fourth end portion 222 of the second word line 22 are dummy portions of the word lines excluding the gates of the transistors. However, the first end portion 211 and the second end portion 212 of the first word line 21 and the third end portion 221 and the fourth end portion 222 of the second word line 22 may be used to connect the contact structure (e.g., the first end portion 211 connecting the first contact structure 31 and the fourth end portion 222 connecting the second contact structure 32). Since the end portions of the word lines may bend easily, the first end portion 211, the second end portion 212, the third end portion 221, and the fourth end portion 222 being the dummy portions can prevent the damage caused by bending to influence the performance of the word lines. Moreover, when two word lines are disposed beside each other, the dummy portions can prevent the bent word lines from being too close to each other to cause an electrical short and/or signal interference. In some embodiments, the first end portion 211, the second end portion 212, and the first middle portion 213 are continuous along the first direction X, and the third end portion 221, the fourth end portion 222, and the second middle portion 223 are continuous along the first direction X.

In some embodiments, the top surface 211TS of the first end portion 211 and the top surface 212TS of the second end portion 212 being lower than the top surface 213TS of the first middle portion 213 and the top surface 221TS of the third end portion 221 and the top surface 222TS of the fourth end portion 222 being lower than the top surface 223TS of the second middle portion 223 are caused by removing portions (e.g., inside the regions enclosed by the dashed lines of FIG. 1) disposed originally on the first end portion 211, the second end portion 212, the third end portion 221, and the fourth end portion 222 while the corresponding portions are remained on the first middle portion 213 and the second middle portion 223 in forming the semiconductor structure of the present disclosure (discussed later). In some embodiments, the top surface 211TS of the first end portion 211, the top surface 212TS of the second end portion 212, the top surface 221TS of the third end portion 221, and the top surface 222TS of the fourth end portion 222 are on the same plane. In some embodiments, the top surface 213TS of the first middle portion 213 and the top surface 223TS of the second middle portion 223 are on the same plane. In some embodiments, a height 213H of the first middle portion 213 is larger than a height 211H of the first end portion 211 and a height 212H of the second end portion 212, and a height 223H of the second middle portion 223 is larger than a height 221H of the third end portion 221 and a height 222H of the fourth end portion 222. In some embodiments, the height 211H of the first end portion 211, the height 212H of the second end portion 212, the height 221H of the third end portion 221, and the height 222H of the fourth end portion 222 are the same. In some embodiments, the height 213H of the first middle portion 213 and the height 223H of the second middle portion 223 are the same.

In some embodiments, the first middle portion 213 includes a high work function layer 2131H and a low work function layer 2132L disposed on the high work function layer 2131H, in which the top surface 213TS of the first middle portion 213 is the top surface of the low work function layer 2132L, and a work function of the high work function layer 2131H is larger than a work function of the low work function layer 2132L. In some embodiments, the work function of the high work function layer 2131H is preferably from 4.3 eV to 4.7 eV, for example, 4.3 eV, 4.4 eV, 4.5 eV, 4.6 eV, or 4.7 eV. In some embodiments, the work function of the low work function layer 2132L is preferably from 4.0 eV to 4.4 eV, for example, 4.0 eV, 4.1 eV, 4.2 eV, 4.3 eV, or 4.4 eV. In some embodiments, the first end portion 211 includes a work function layer 2111W and the second end portion 212 includes a work function layer 2121W, in which the top surface 211TS of the first end portion 211 is the top surface of the work function layer 2111W, and the top surface 212TS of the second end portion 212 is the top surface of the work function layer 2121W. In some embodiments, a work function of the work function layer 2111W of the first end portion 211 and a work function of the work function layer 2121W of the second end portion 212 is larger than the work function of the low work function layer 2132L of the first middle portion 213. In some embodiments, the work function of the work function layer 2111W of the first end portion 211 and the work function of the work function layer 2121W of the second end portion 212 are independently and preferably from 4.3 eV to 4.7 eV, for example, 4.3 eV, 4.4 eV, 4.5 eV, 4.6 eV, or 4.7 eV.

In some embodiments, the second middle portion 223 includes a high work function layer 2231H and a low work function layer 2232L disposed on the high work function layer 2231H, in which the top surface 223TS of the second middle portion 223 is the top surface of the low work function layer 2232L, and a work function of the high work function layer 2231H is larger than a work function of the low work function layer 2232L. In some embodiments, the work function of the high work function layer 2231H is preferably from 4.3 eV to 4.7 eV, for example, 4.3 eV, 4.4 eV, 4.5 eV, 4.6 eV, or 4.7 eV. In some embodiments, the work function of the low work function layer 2232L is preferably from 4.0 eV to 4.4 eV, for example, 4.0 eV, 4.1 eV, 4.2 eV, 4.3 eV, or 4.4 eV. In some embodiments, the third end portion 221 includes a work function layer 2211W and the fourth end portion 222 includes a work function layer 2221W, in which the top surface 221TS of the third end portion 221 is the top surface of the work function layer 2211W and the top surface 222TS of the fourth end portion 222 is the top surface of the work function layer 2221W. In some embodiments, a work function of the work function layer 2211W of the third end portion 221 and a work function of the work function layer 2221W of the fourth end portion 222 is larger than the work function of the low work function layer 2232L of the second middle portion 223. In some embodiments, the work function of the work function layer 2211W of the third end portion 221 and the work function of the work function layer 2221W of the fourth end portion 222 are independently and preferably from 4.3 eV to 4.7 eV, for example, 4.3 eV, 4.4 eV, 4.5 eV, 4.6 eV, or 4.7 eV.

In some embodiments, the top surface of the high work function layer 2131H of the first middle portion 213, the top surface of the work function layer 2111W of the first end portion 211, the top surface of the work function layer 2121W of the second end portion 212, the top surface of the high work function layer 2231H of the second middle portion 223, the top surface of the work function layer 2211W of the third end portion 221, and the top surface of the work function layer 2221W of the fourth end portion 222 are on the same plane.

In some embodiments, the work functions of the high work function layer 2131H of the first middle portion 213, the high work function layer 2231H of the second middle portion 223, the work function layer 2111W of the first end portion 211, the work function layer 2121W of the second end portion 212, the work function layer 2211W of the third end portion 221, and the work function layer 2221W of the fourth end portion 222 are the same. In some embodiments, the work functions of the low work function layer 2132L of the first middle portion 213 and the low work function layer 2232L of the second middle portion 223 are the same.

In some embodiments, the high work function layer 2131H of the first middle portion 213, the work function layer 2111W of the first end portion 211, and the work function layer 2121W of the second end portion 212 are continuous along the first direction X, and the high work function layer 2231H of the second middle portion 223, the work function layer 2211W of the third end portion 221, and the work function layer 2221W of the fourth end portion 222 are continuous along the first direction X.

In some embodiments, the low work function layer 2132L of the first middle portion 213 and the low work function layer 2232L of the second middle portion 223 are used as the gates of the transistors. In some embodiments, the work function layer 2111W of the first end portion 211 is in direct contact with the first contact structure 31, and the work function layer 2221W of the fourth end portion 222 is in direct contact with the second contact structure 32.

In some embodiments, the first middle portion 213 includes a metal-containing layer 2131M and a silicon-containing conductive layer 2132S disposed on the metal-containing layer 2131M, in which the top surface 213TS of the first middle portion 213 is the top surface of the silicon-containing conductive layer 2132S. In some embodiments, the metal-containing layer 2131M of the first middle portion 213 includes tungsten, and the silicon-containing conductive layer 2132S of the first middle portion 213 includes polysilicon, for example, N-type conducting dopant doped polysilicon. In some embodiments, the first end portion 211 includes a metal-containing layer 2111M and the second end portion 212 includes a metal-containing layer 2121M, in which the top surface 211TS of the first end portion 211 is the top surface of the metal-containing layer 2111M of the first end portion 211 and the top surface 212TS of the second end portion 212 is the top surface of the metal-containing layer 2121M of the second end portion 212. In some embodiments, the metal-containing layer 2111M of the first end portion 211 and the metal-containing layer 2121M of the second end portion 212 include tungsten.

In some embodiments, the second middle portion 223 includes a metal-containing layer 2231M and a silicon-containing conductive layer 2232S disposed on the metal-containing layer 2231M, in which the top surface 223TS of the second middle portion 223 is the top surface of the silicon-containing conductive layer 2232S. In some embodiments, the metal-containing layer 2231M of the second middle portion 223 includes tungsten, and the silicon-containing conductive layer 2232S of the second middle portion 223 includes polysilicon, for example, N-type conducting dopant doped polysilicon. In some embodiments, the third end portion 221 includes a metal-containing layer 2211M and the fourth end portion 222 includes a metal-containing layer 2221M, in which the top surface 221TS of the third end portion 221 is the top surface of the metal-containing layer 2211M of the third end portion 221 and the top surface 222TS of the fourth end portion 222 is the top surface of the metal-containing layer 2221M of the fourth end portion 222. In some embodiments, the metal-containing layer 2211M of the third end portion 221 and the metal-containing layer 2221M of the fourth end portion 222 include tungsten.

In some embodiments, the top surface of the metal-containing layer 2131M of the first middle portion 213, the top surface of the metal-containing layer 2111M of the first end portion 211, the top surface of the metal-containing layer 2121M of the second end portion 212, the top surface of the metal-containing layer 2231M of the second middle portion 223, the top surface of the metal-containing layer 2211M of the third end portion 221, and the top surface of the metal-containing layer 2221M of the fourth end portion 222 are on the same plane.

In some embodiments, the metal-containing layer 2131M of the first middle portion 213, the metal-containing layer 2111M of the first end portion 211, and the metal-containing layer 2121M of the second end portion 212 are continuous along the first direction X, and the metal-containing layer 2231M of the second middle portion 223, the metal-containing layer 2211M of the third end portion 221, and the metal-containing layer 2221M of the fourth end portion 222 are continuous along the first direction X.

In some embodiments, the silicon-containing conductive layer 2132S of the first middle portion 213 and the silicon-containing conductive layer 2232S of the second middle portion 223 are used as the gates of the transistors. In some embodiments, the metal-containing layer 2111M of the first end portion 211 is in direct contact with the first contact structure 31, and the metal-containing layer 2221M of the fourth end portion 222 is in direct contact with the second contact structure 32.

In the first word line 21, the length 212L of the second end portion 212 along the first direction X is larger than the length 211L of the first end portion 211 along the first direction X, and in the second word line 22, the length 221L of the third end portion 221 along the first direction X is larger than the length 222L of the fourth end portion 222 along the first direction X. In the embodiments including the portions disposed originally on the first end portion 211, the second end portion 212, the third end portion 221, and the fourth end portion 222 being removed in forming the semiconductor structure of the present disclosure (discussed later), the length 212L of the second end portion 212 being larger than the length 211L of the first end portion 211 and the length 221L of the third end portion 221 being larger than the length 222L of the fourth end portion 222 may be caused by the portion originally on the second end portion 212 having the length larger than the length of the portion originally on the first end portion 211 and the portion originally on the third end portion 221 having the length larger than the length of the portion originally on the fourth end portion 222.

In some embodiments, a horizontal distance H1 along the first direction X and from a boundary 211B of the first end portion 211 closest to the second end portion 212 to the center of the first contact structure 31 is preferably from 100 nm to 1000 nm, for example, 100 nm, 250 nm, 500 nm, 750 nm, or 1000 nm. In some embodiments, a boundary 212B of the second end portion 212 closest to the first end portion 211 is closer to the center of the first word line 21 compared with the boundary 211B of the first end portion 211. In some embodiments, a horizontal distance H4 along the first direction X and from a boundary 222B of the fourth end portion 222 closest to the third end portion 221 to the center of the second contact structure 32 is preferably from 100 nm to 1000 nm, for example, 100 nm, 250 nm, 500 nm, 750 nm, or 1000 nm. In some embodiments, a boundary 221B of the third end portion 221 closest to the fourth end portion 222 is closer to the center of the second word line 22 compared with the boundary 222B of the fourth end portion 222. In some embodiments, the horizontal distance H1 is equal to the horizontal distance H4.

In some embodiments, a virtual line 42 passes through the center of the second contact structure 32 and a point 212P of the second end portion 212 in a second direction Y on the substrate 11 and perpendicular to the first direction X, and a horizontal distance H2 along the first direction X and from the boundary 212B of the second end portion 212 to the point 212P is preferably from 200 nm to 3000 nm, for example, 200 nm, 600 nm, 1000 nm, 1400 nm, 1800 nm, 2200 nm, 2600 nm, or 3000 nm. In some embodiments, a virtual line 41 passes through the center of the first contact structure 31 and a point 221P of the third end portion 221 in the second direction Y, and a horizontal distance H3 along the first direction X and from the boundary 221B of the third end portion 221 to the point 221P is preferably from 200 nm to 3000 nm, for example, 200 nm, 600 nm, 1000 nm, 1400 nm, 1800 nm, 2200 nm, 2600 nm, or 3000 nm. In some embodiments, the horizontal distance H2 is equal to the horizontal distance H3. In some embodiments, the horizontal distance H2 and the horizontal distance H3 are larger than the horizontal distance H1 and the horizontal distance H4. In some embodiments, the boundary 212B of the second end portion 212 is closer to a virtual connecting line between the center of the first word line 21 and the center of the second word line 22 compared with the boundary 222B of the fourth end portion 222. In some embodiments, the boundary 221B of the third end portion 221 is closer to a virtual connecting line between the center of the first word line 21 and the center of the second word line 22 compared with the boundary 211B of the first end portion 211.

In some embodiments, the first contact structure 31 and the second contact structure 32 are conductive and extend vertically away from the substrate 11 to connect the first word line 21 and the second word line 22 to the components disposed on any suitable layers above the first word line 21 and the second word line 22. In some embodiments, the first contact structure 31 includes a first contact plug 311 and a first wire 312 disposed on the first contact plug 311, and the second contact structure 32 includes a second contact plug 321 and a second wire 322 disposed on the second contact plug 321. In some embodiments, the first contact plug 311, the first wire 312, the second contact plug 321, and the second wire 322 include any suitable conductive material. In the embodiments including the numbers of the first contact structure 31 and the second contact structure 32 being plurals, the first contact structures 31 and the second contact structures 32 are arranged in a zigzag shape on the substrate 11.

Next, the substrate 11 is discussed. The substrate 11 may be any suitable substrate. In some embodiments, the substrate 11 is a semiconductor substrate and includes a semiconductor material. In some embodiments, the semiconductor material includes an elemental semiconductor material, for example, carbon, monocrystalline silicon, polycrystalline silicon, amorphous silicon, germanium, tin, sulfur, selenium, tellurium, or the like; a compound semiconductor material, for example, silicon carbide, nitride boron, aluminum nitride, gallium nitride, gallium phosphide, gallium arsenide, indium phosphide, indium arsenide, indium antimonide, zinc oxide, or the like; an alloy semiconductor material, for example, SiGe, AlGaAs, InGaAs, InGaP, AlInAs, GaAsP, AlGaN, InGaN, AlGaInP, or the like; or combinations thereof. In some embodiments, the first word line 21 and the second word line 22 are embedded in the substrate 11.

In some embodiments, the substrate 11 includes an isolation region 111 and active regions 112, in which the active regions 112 are separated from each other by the isolation region 111, as shown in FIG. 1. In some embodiments, each one of the active regions 112 includes an N-type conducting dopant or a P-type conducting dopant. In some embodiments, the isolation region 111 includes an electrical isolation material, for example, silicon dioxide.

In some embodiments, the active regions 112 include longer active regions 1121 and shorter active regions 1122, in which a length 1121L of each one of the longer active regions 1121 is larger than a length 1122L of each one of the shorter active regions 1122, the first end portion 211 and the second end portion 212 of the first word line 21 and the third end portion 221 and the fourth end portion 222 of the second word line 22 are disposed on the longer active regions 1121, and the first middle portion 213 of the first word line 21 and the second middle portion 223 of the second word line 22 are disposed on the shorter active regions 1122. The first word line 21 and the second word line 22 further reduce stress when the first end portion 211, the second end portion 212, the third end portion 221, and the fourth end portion 222 are disposed on the longer active regions 1121 having the lengths 1121L larger than the lengths 1122L of the shorter active regions 1122. In some embodiments, the longer active regions 1121 surround the shorter active regions 1122.

In some embodiments, a top surface TS213 of a portion of the substrate 11 around the first middle portion 213 is higher than a top surface TS211 of a portion of the substrate 11 around the first end portion 211 and a top surface TS212 of a portion of the substrate 11 around the second end portion 212, and a top surface TS223 of a portion of the substrate 11 around the second middle portion 223 is higher than a top surface TS221 of a portion of the substrate 11 around the third end portion 221 and a top surface TS222 of a portion of the substrate 11 around the fourth end portion 222. In some embodiments (see FIG. 2B), around the first middle portion 213, around the second middle portion 223, around the third end portion 221, and around the fourth end portion 222, the top surface of the active region 112 is lower than the top surface of the isolation region 111. In the embodiments including the portions disposed originally on the first end portion 211, the second end portion 212, the third end portion 221, and the fourth end portion 222 being removed in forming the semiconductor structure of the present disclosure (discussed later), portions of the substrate 11 around the first end portion 211, the second end portion 212, the third end portion 221, and the fourth end portion 222 may be removed together to form the top surfaces of the remaining portions of the substrate 11 around the first end portion 211, the second end portion 212, the third end portion 221, and the fourth end portion 222 being lower than the top surfaces of the portions around the first middle portion 213 and the second middle portion 223. In addition, since the materials of the active region 112 and the isolation region 111 are different, after the portions of the substrate 11 around the first end portion 211, the second end portion 212, the third end portion 221, and the fourth end portion 222 are removed, the top surface of the active region 112 may be lower than the top surface of the isolation region 111 in the remaining portions of the substrate 11 around the first end portion 211, the second end portion 212, the third end portion 221, and the fourth end portion 222. Moreover, in the embodiments including the numbers of the first word line 21, the first contact structure 31, the second word line 22, and the second contact structure 32 being plurals, the height difference on the top surface of the substrate 11 leads to jagged sidewalls 11JS (see FIG. 1) of the substrate 11 along the first direction X and between the middle portions (e.g., the first middle portions 213 and the second middle portions 223) of the word lines and the end portions (e.g., the first end portions 211, the second end portions 212, the third end portions 221, and the fourth end portions 222) of the word lines.

In some embodiments, the semiconductor structure further includes a hard mask layer 51 on a portion of the substrate 11 around the first middle portion 213 of the first word line 21 and around the second middle portion 223 of the second word line 22. The hard mask layer 51 may be used as an etch mask to form the trenches in the substrate 11, and the trenches may be filled with the first word line 21 and the second word line 22 (discussed later). In the embodiments including the portions disposed originally on the first end portion 211, the second end portion 212, the third end portion 221, and the fourth end portion 222 being removed in forming the semiconductor structure of the present disclosure (discussed later), portions of the hard mask layer 51 disposed originally on the substrate 11 around the first end portion 211 and the second end portion 212 of the first word line 21 and around the third end portion 221 and the fourth end portion 222 of the second word line 22 may be removed together. In some embodiments, the hard mask layer 51 includes silicon nitride.

In some embodiments, the semiconductor structure further includes a dielectric layer 52 between the first word line 21 and the substrate 11 and between the second word line 22 and the substrate 11 to provide the electrical isolation. In some embodiments, the dielectric layer 52 includes any suitable dielectric material, for example, silicon oxide.

In some embodiments, the semiconductor structure further includes a dielectric layer 53 on the first word line 21 and the second word line 22 to provide the electrical isolation. In some embodiments, the dielectric layer 53 is in direct contact with portions of the substrate 11 around the first end portion 211 and the second end portion 212 of the first word line 21 and portions of the substrate 11 around the third end portion 221 and the fourth end portion 222 of the second word line 22, and the dielectric layer 53 separates from a portion of the substrate 11 around the first middle portion 213 of the first word line 21 and around the second middle portion 223 of the second word line 22 by the dielectric layer 52. In some embodiments, the semiconductor structure further includes an interlayer dielectric layer 54 on the dielectric layer 53. In some embodiments, the first contact structure 31 and the second contact structure 32 penetrate the dielectric layer 53 and the interlayer dielectric layer 54. In some embodiments, the dielectric layer 53 and the interlayer dielectric layer 54 include any suitable dielectric material, for example, silicon oxide.

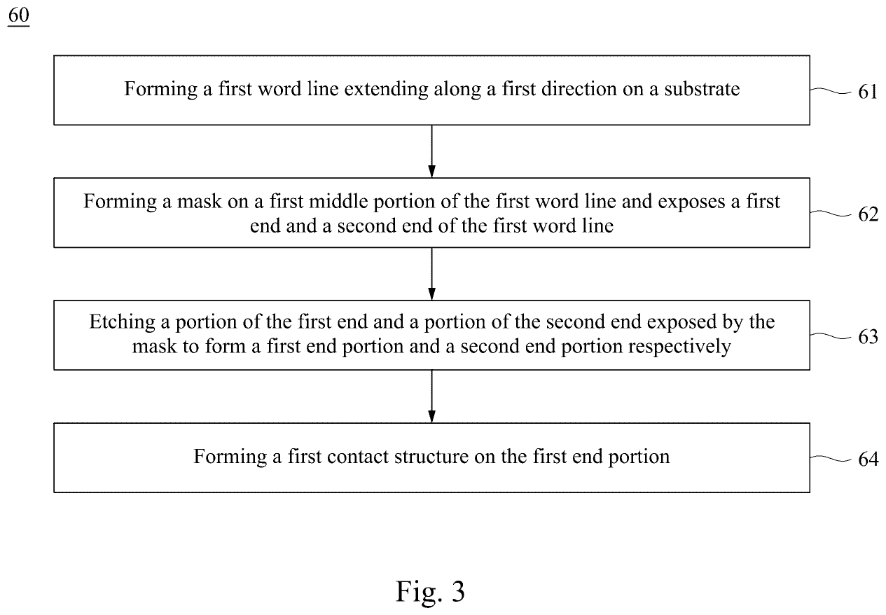

The present disclosure also provides a method 60 of forming the semiconductor structure provided above. In FIG. 3, the method 60 includes an operation 61 to an operation 64. When reading FIG. 3, please also refer to FIGS. 1, 2A to 2D, and 4A to 10D. The operation 61 includes forming a first word line 21 extending along a first direction X on a substrate 11. The operation 62 includes forming a mask 72 on a first middle portion 213 of the first word line 21 and exposes a first end 211′ and a second end 212′ of the first word line 21, in which a length 212′L of the second end 212′ exposed by the mask 72 is larger than a length 211′L of the first end 211′ exposed by the mask 72, and the first middle portion 213 is between the first end 211′ and the second end 212′. The operation 63 includes etching a portion of the first end 211′ and a portion of the second end 212′ of the first word line 21 exposed by the mask 72 to form a first end portion 211 and a second end portion 212 of the first word line 21 respectively, in which a top surface 211TS of the first end portion 211 and a top surface 212TS of the second end portion 212 are lower than a top surface 213TS of the first middle portion 213. The operation 64 includes forming a first contact structure 31 on the first end portion 211. The method of the present disclosure is described in detail with the following embodiments.

See FIGS. 4A, 4B, 4C, and 4D. Before the operation 61 is performed, in some embodiments, the method 60 further includes receiving the substrate 11 including the isolation region 111 and the active regions 112, in which the active regions 112 includes the longer active regions 1121 and the shorter active regions 1122, and in some embodiments, the method 60 further includes forming the hard mask layer 51 on the substrate 11 by any suitable deposition method, for example, a chemical vapor deposition method or a physical vapor deposition method. It is noted that portions of the substrate 11 and portions of the hard mask layer 51 shown in FIGS. 4A, 4B, 4C, and 4D will be removed in the following operations in order to form the first word line 21 and the second word line 22 described in FIGS. 1 and 2A to 2D.

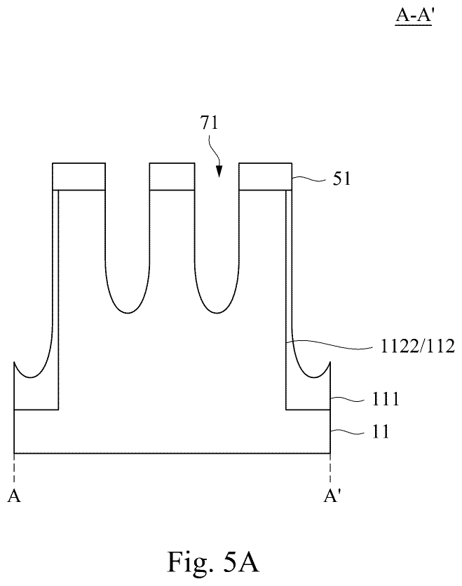

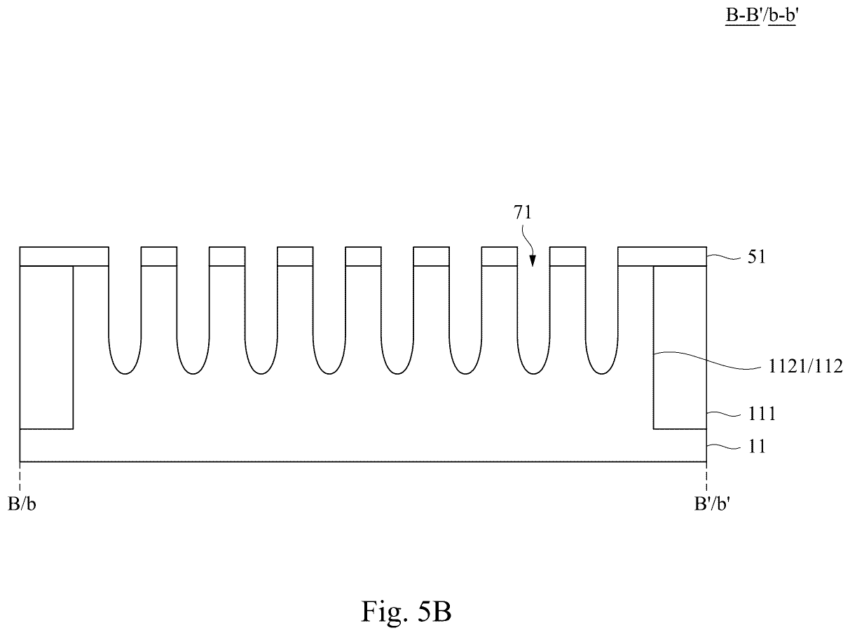

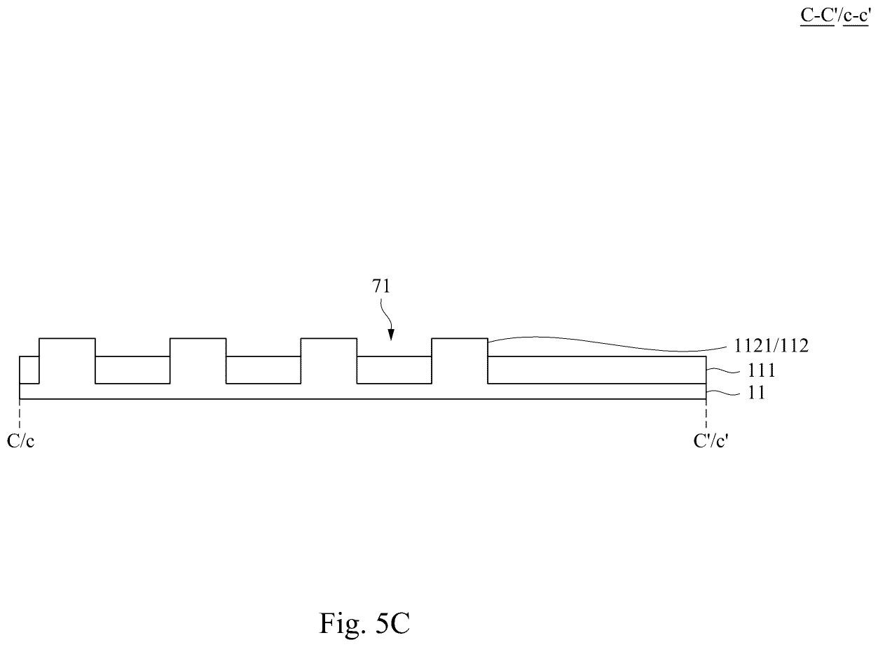

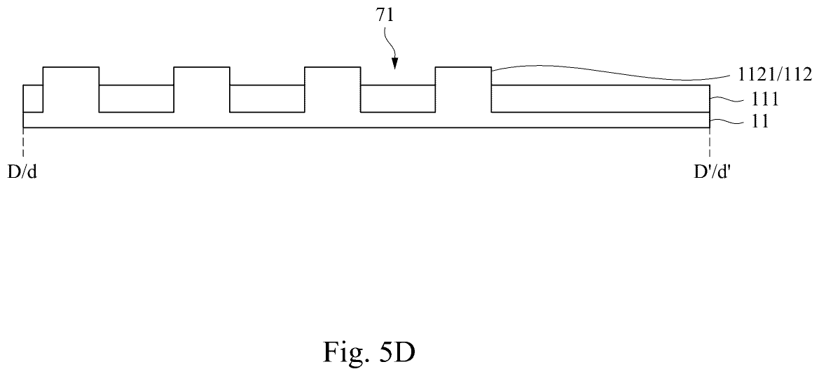

See FIGS. 5A, 5B, 5C, and 5D. Before the operation 61 is performed, in some embodiments, the method 60 further includes etching portions of the substrate 11 and portions of the hard mask layer 51 to form trenches 71 by any suitable etching method, for example, a dry etching method or a wet etching method. The trenches 71 will be filled with the first word line 21 and the second word line 22 in the following operations, so in some embodiments, the positions of the trenches 71 correspond to the positions of the first word line 21 and the second word line 22 described in FIGS. 1 and 2A to 2D, for example, the trenches 71 extending along the first direction X, and so on. In some embodiments, etching portions of the hard mask layer 51 is performed by using a patterned photoresist layer (not drawn) on the hard mask layer 51 to transfer the pattern of the patterned photoresist layer to the hard mask layer 51, and etching portions of the substrate 11 is performed by using the hard mask layer 51 having the pattern transferred from the patterned photoresist layer as an etch mask to transfer the pattern further to the substrate 11. Since the materials of the active region 112 and the isolation region 111 are different, in the embodiments that the etch rate of the isolation region 111 is larger than the etch rate of the active region 112, the etch depth exposing the isolation region 111 is larger than the etch depth exposing the active region 112 in the trench 71 (see FIGS. 5A, 5C, and 5D). It is noted that portions of the substrate 11 and portions of the hard mask layer 51 shown in FIG. 5B may be removed further in the following operations when forming the first end portion 211 and the second end portion 212 of the first word line 21 and the third end portion 221 and the fourth end portion 222 of the second word line 22.

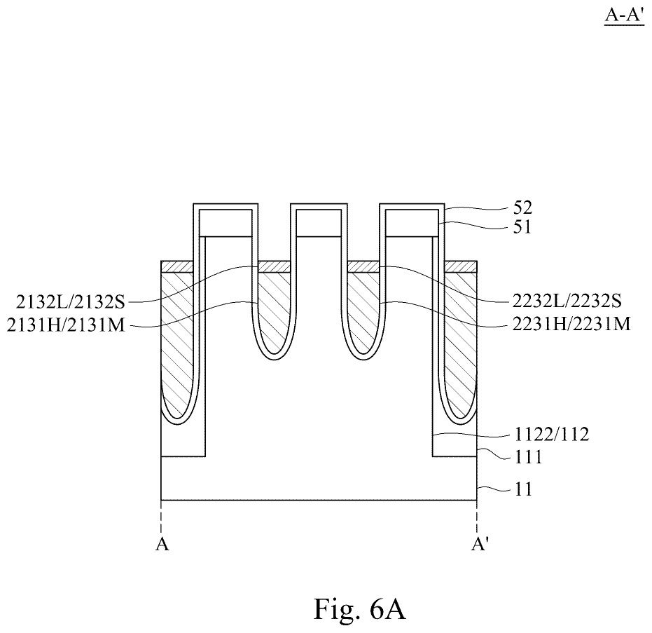

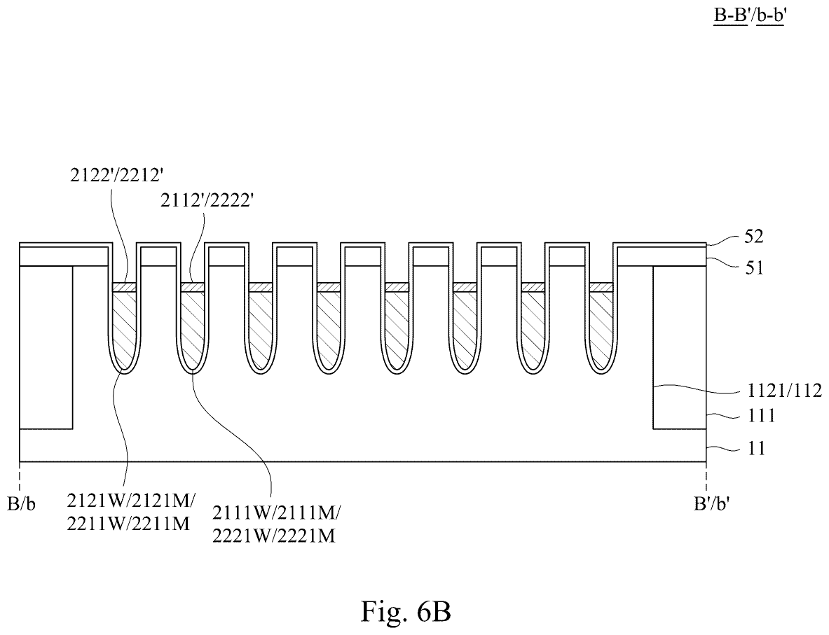

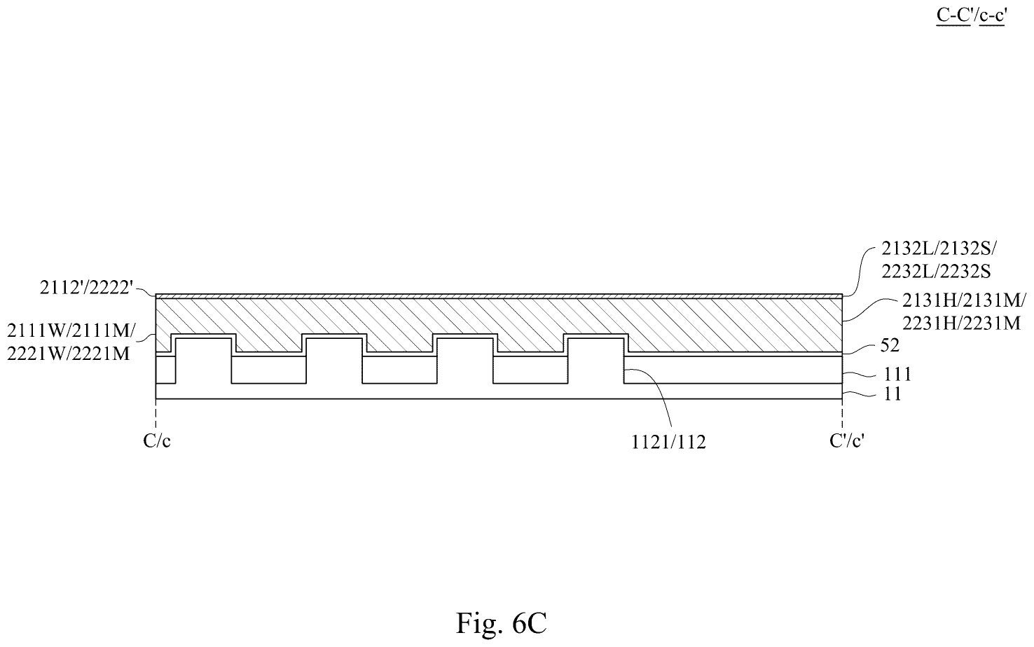

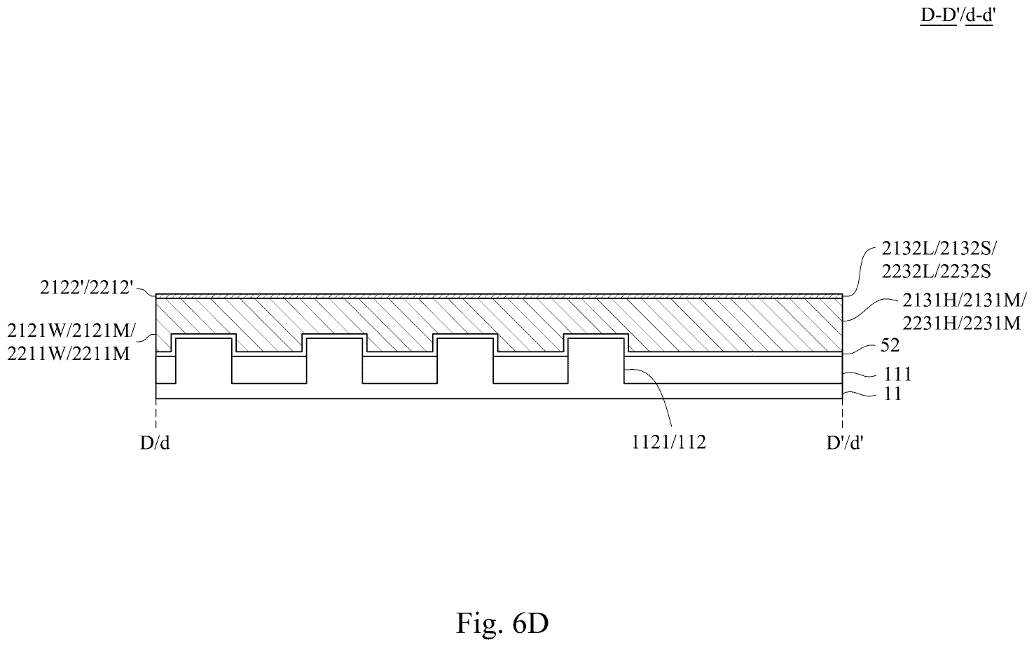

See FIGS. 6A, 6B, 6C, and 6D. In the operation 61, the first word line 21 and the second word line 22 (in some embodiments) are formed in the trenches 71 by any suitable deposition method, for example, a chemical vapor deposition method or a physical vapor deposition method. After the operation 61, the first middle portion 213 of the first word line 21 described in FIGS. 1 and 2A is formed, and in some embodiments, the second middle portion 223 of the second word line 22 described in FIGS. 1 and 2A is formed. It is noted that, after the operation 61 and before the following operations, the end portions of the first word line 21 and the second word line 22 are the precursors (i.e., the first end 211′, the second end 212′, the third end 221′, and the fourth end 222′ in the present disclosure) of the first end portion 211, the second end portion 212, the third end portion 221, and the fourth end portion 222. For example, the first end 211′ includes the work function layer 2111W or the metal-containing layer 2111M, and includes a layer 2112′ on the work function layer 2111W or on the metal-containing layer 2111M; the second end 212′ includes the work function layer 2121W or the metal-containing layer 2121M, and includes a layer 2122′ on the work function layer 2121W or on the metal-containing layer 2121M; the third end 221′ includes the work function layer 2211W or the metal-containing layer 2211M, and includes a layer 2212′ on the work function layer 2211W or on the metal-containing layer 2211M; and the fourth end 222′ includes the work function layer 2221W or the metal-containing layer 2221M, and includes a layer 2222′ on the work function layer 2221W or on the metal-containing layer 2221M. The layer 2112′ of the first end 211′, the layer 2122′ of the second end 212′, the layer 2212′ of the third end 221′, and the layer 2222′ of the fourth end 222′ will be removed in the following operations to form the first end portion 211, the second end portion 212, the third end portion 221, and the fourth end portion 222, respectively.

In some embodiments, the layer 2112′ of the first end 211′, the layer 2122′ of the second end 212′, the layer 2212′ of the third end 221′, and the layer 2222′ of the fourth end 222′ are low work function layers having the work functions smaller than the work functions of the work function layer 2111W, the work function layer 2121W, the work function layer 2211W, and the work function layer 2221W. In some embodiments, the work functions of the layer 2112′, the layer 2122′, the layer 2212′, and the layer 2222′ are independently and preferably from 4.0 eV to 4.4 eV, for example, 4.0 eV, 4.1 eV, 4.2 eV, 4.3 eV, or 4.4 eV. In some embodiments, the layer 2112′ of the first end 211′, the layer 2122′ of the second end 212′, the layer 2212′ of the third end 221′, and the layer 2222′ of the fourth end 222′ are silicon-containing conductive layers including polysilicon, for example, N-type conducting dopant doped polysilicon.

Continuously see FIGS. 6A, 6B, 6C, and 6D. In some embodiments, the method 60 further includes forming the dielectric layer 52 on the substrate 11 by any suitable deposition method, for example, a chemical vapor deposition method or a physical vapor deposition method, before forming the first word line 21 and the second word line 22 in the operation 61. It is noted that portions of the dielectric layer 52 shown in FIG. 6B may be removed in the following operations when forming the first end portion 211 and the second end portion 212 of the first word line 21 and the third end portion 221 and the fourth end portion 222 of the second word line 22.

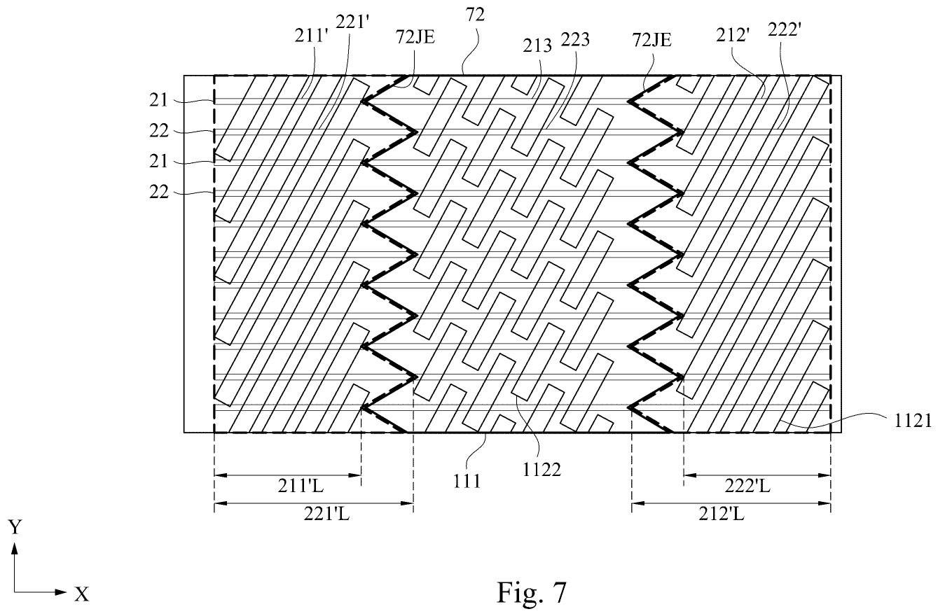

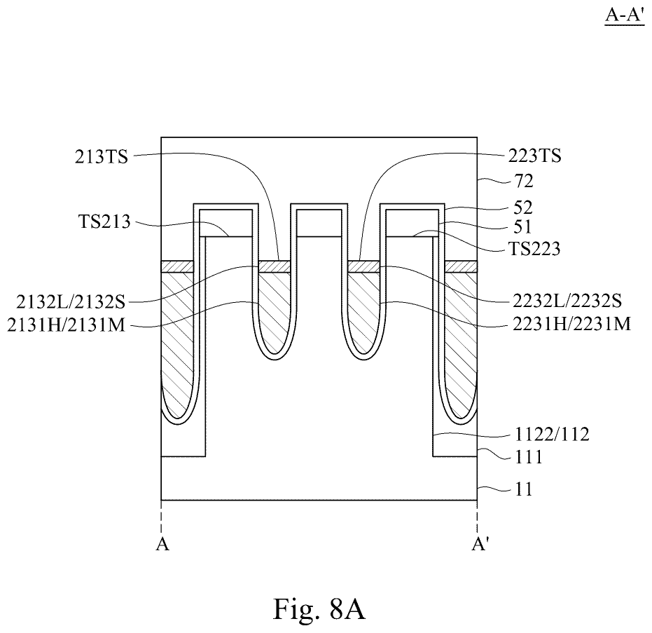

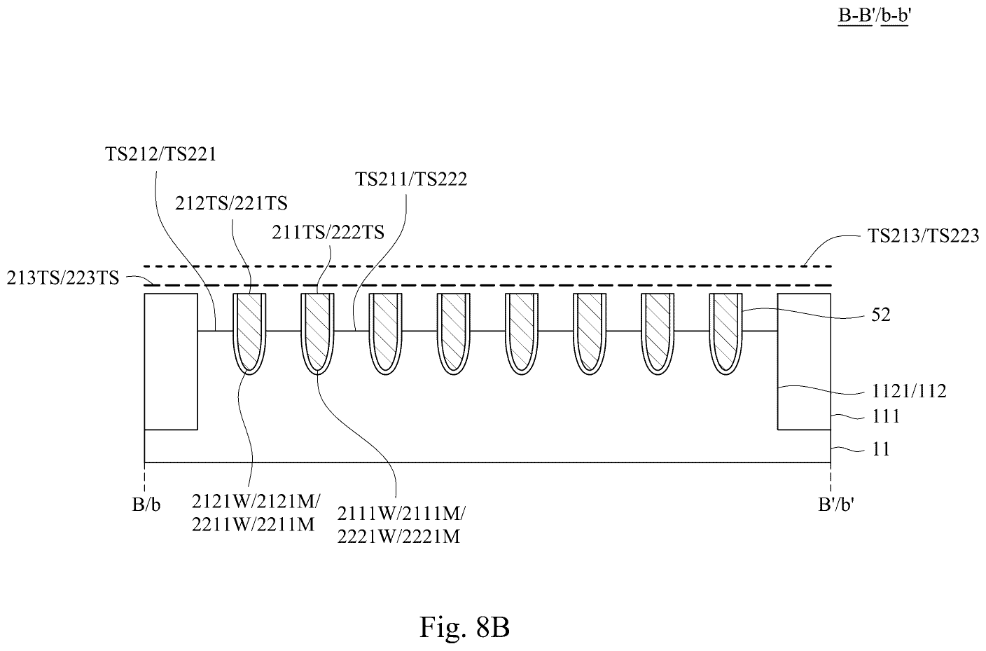

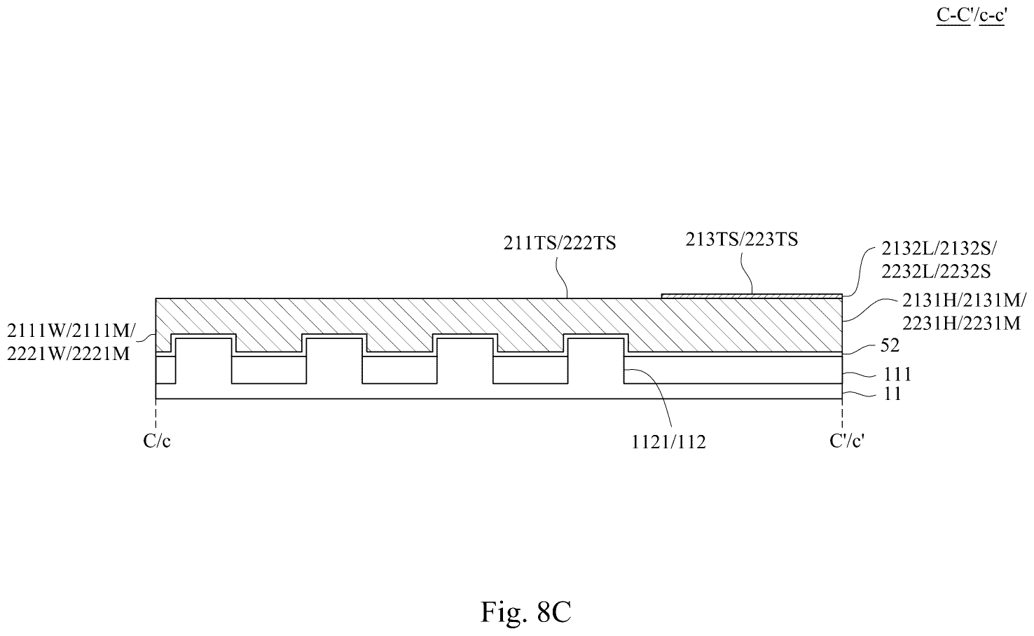

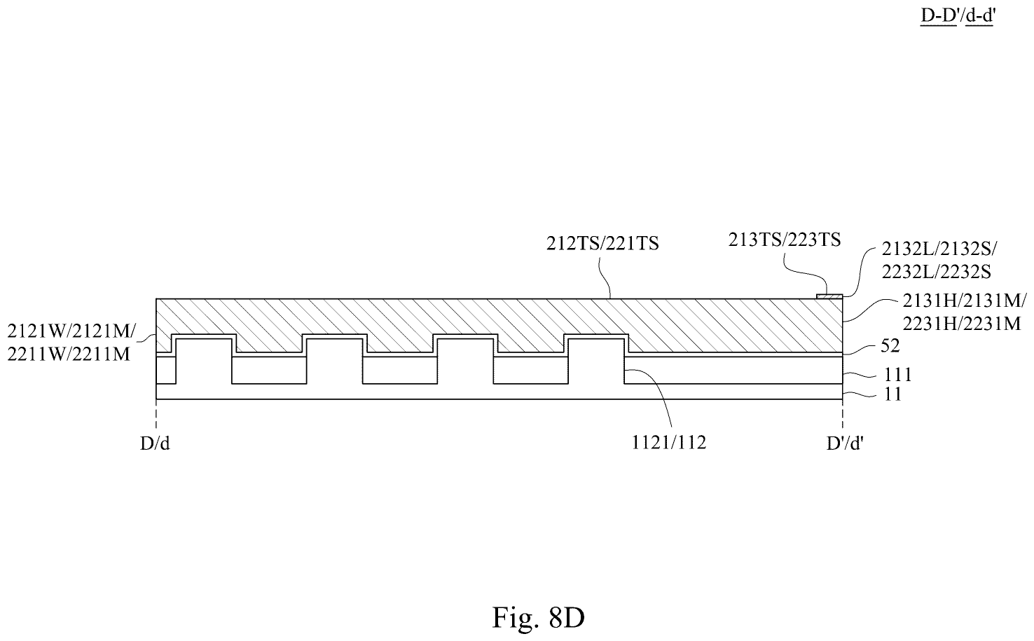

See FIGS. 7, 8A, 8B, 8C, and 8D. In the operation 62, a mask 72 is formed on the first middle portion 213 of the first word line 21 and exposes the first end 211′ and the second end 212′ of the first word line 21, and in some embodiments, the mask 72 is further formed on the second middle portion 223 of the second word line 22 and further exposes the third end 221′ and the fourth end 222′ of the second word line 22. The components covered by the mask 72 will not be removed in the following operations, but the components (e.g., the layer 2112′, the layer 2122′, the layer 2212′, and the layer 2222′, and portions of the substrate 11, the hard mask layer 51, and the dielectric layer 52 around the layer 2112′, the layer 2122′, the layer 2212′, and the layer 2222′) exposed by the opening (e.g., the regions enclosed by the dashed lines of FIG. 7) of the mask 72 will be removed in the following operations. In some embodiments, the mask 72 is formed by any suitable deposition method, for example, a chemical vapor deposition method or a physical vapor deposition method. In some embodiments, the mask 72 has jagged edges 72JE along the first direction X and between the middle portions (e.g., the first middle portions 213 and the second middle portions 223) of the word lines and the end portions (e.g., the first end 211′, the second end 212′, the third end 221′, and the fourth end 222′) of the word lines. A length 212′L (corresponding to the length 212L of the second end portion 212) of the second end 212′ exposed by the mask 72 is larger than a length 211′L (corresponding to the length 211L of the first end portion 211) of the first end 211′ exposed by the mask 72. A length 221′L (corresponding to the length 221L of the third end portion 221) of the third end 221′ exposed by the mask 72 is larger than a length 222′L (corresponding to the length 222L of the fourth end portion 222) of the fourth end 222′ exposed by the mask 72. In some embodiments, the mask 72 includes a photoresist and may be patterned by a photolithography method. In some embodiments, the mask 72 is a hard mask and may include any suitable hard mask material, for example, silicon nitride. In the embodiments that the mask 72 is a hard mask, the hard mask may be patterned by any suitable patterned photoresist layer disposed on the hard mask.

Continuously see FIGS. 7, 8A, 8B, 8C, and 8D. In the operation 63, the layer 2112′ of the first end 211′ and the layer 2122′ of the second end 212′ exposed by the mask 72 are etched to form the first end portion 211 and the second end portion 212, and in some embodiments, the layer 2212′ of the third end 221′ and the layer 2222′ of the fourth end 222′ exposed by the mask 72 are etched to form the third end portion 221 and the fourth end portion 222 of the second word line 22. In some embodiments, when etching portions (i.e., the layer 2112′, the layer 2122′, the layer 2212′, and the layer 2222′) of the first end 211′, the second end 212′, the third end 221′, and the fourth end 222′, portions of the substrate 11, the hard mask layer 51, and the dielectric layer 52 around these portions (i.e., the layer 2112′, the layer 2122′, the layer 2212′, and the layer 2222′) of the first end 211′, the second end 212′, the third end 221′, and the fourth end 222′ are etched together. Since the materials of the active region 112 and the isolation region 111 are different, in the embodiments that the etch rate of the isolation region 111 is larger than the etch rate of the active region 112, after etching the portions of the substrate 11 around the first end 211′, the second end 212′, the third end 221′, and the fourth end 222′, the top surface of the active region 112 is lower than the top surface of the isolation region 111 in the remaining portions of the substrate 11 around the formed first end portion 211, the formed second end portion 212, the formed third end portion 221, and the formed fourth end portion 222 (see FIG. 8B). In some embodiments, the etching may be performed by any suitable etching method, for example, a dry etching method or a wet etching method. Therefore, after the operation 63, the first word line 21, the second word line 22, the substrate 11, the hard mask layer 51, and the dielectric layer 52 described in FIGS. 1 and 2A to 2D are formed.

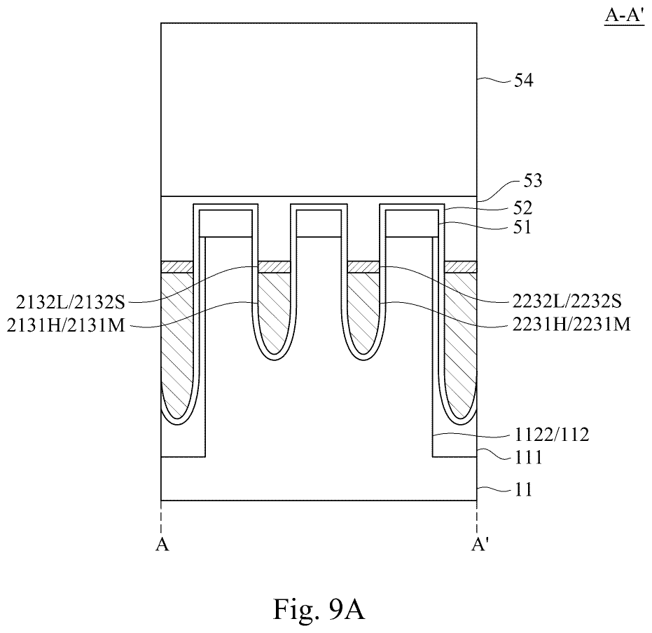

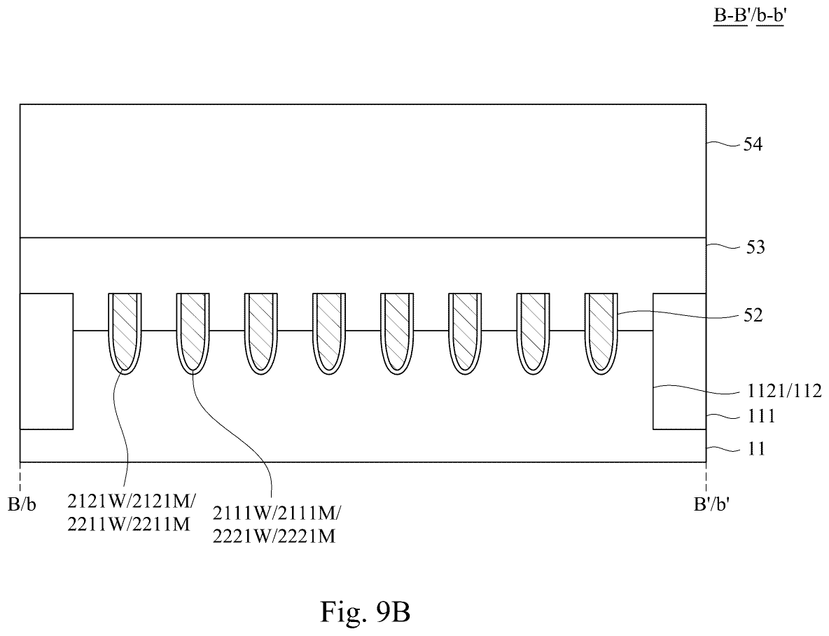

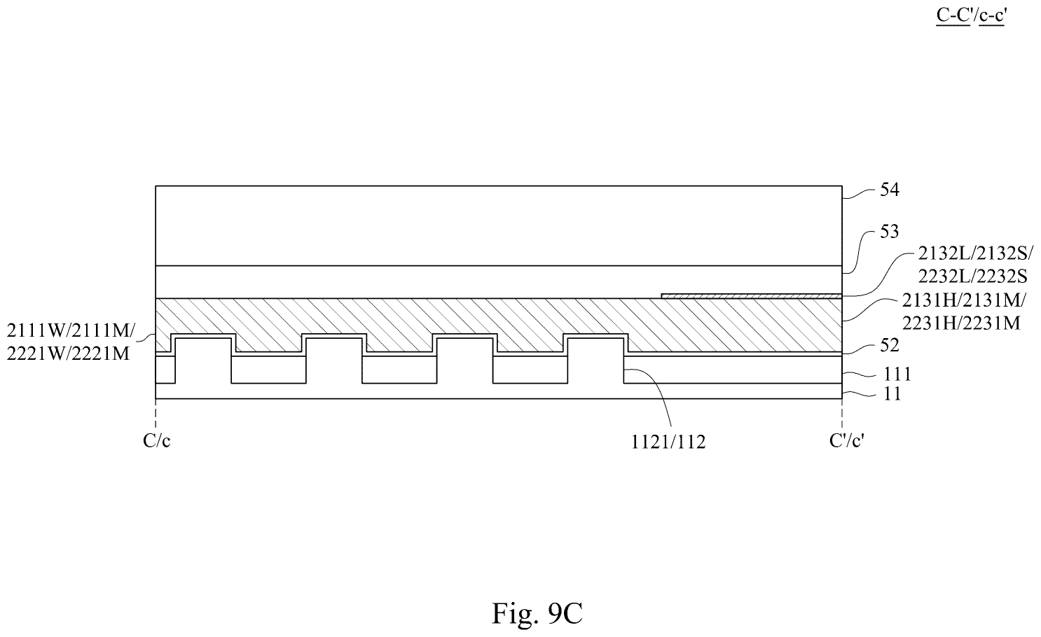

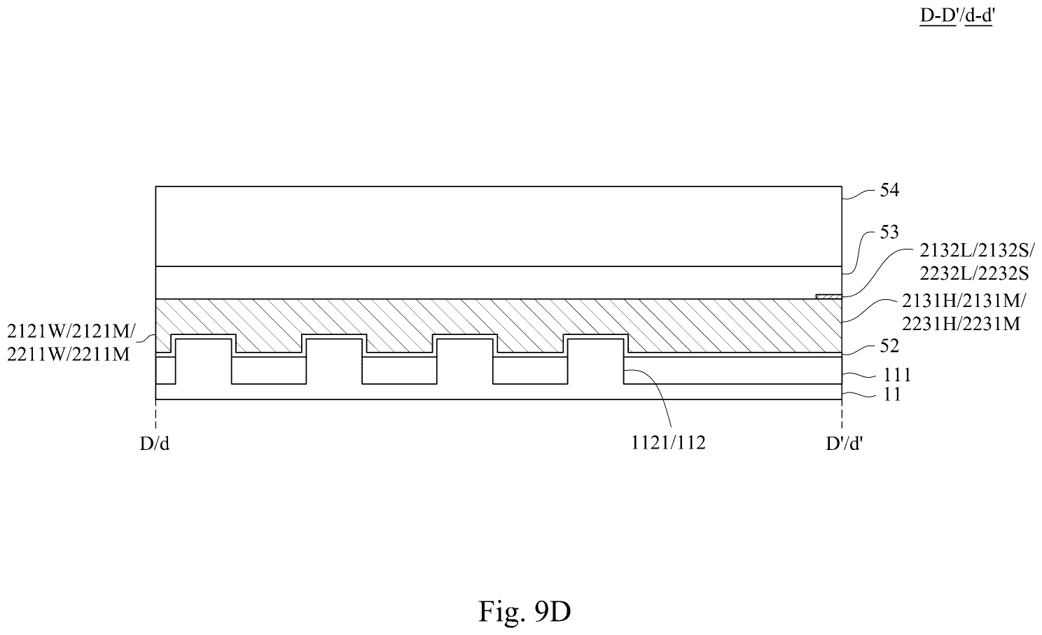

See FIGS. 9A, 9B, 9C, and 9D. After the operation 63, in some embodiments, the method 60 further includes forming the dielectric layer 53 on the first word line 21 and the second word line 22 and forming the interlayer dielectric layer 54 on the dielectric layer 53, by any suitable deposition method, for example, a chemical vapor deposition method or a physical vapor deposition method.

See FIGS. 1, 2A to 2D, 10A, 10B, 10C, and 10D. In the operation 64, the first contact structure 31 including the first contact plug 311 and the first wire 312 is formed on the first end portion 211, and in some embodiments, the second contact structure 32 including the second contact plug 321 and the second wire 322 is formed on the fourth end portion 222, by any suitable deposition method, for example, a chemical vapor deposition method or a physical vapor deposition. In some embodiments, before the operation 64, in some embodiments, openings 73 exposing the first end portion 211 and the fourth end portion 222 are formed in the dielectric layer 53 and the interlayer dielectric layer 54 by any suitable etching method, for example, a dry etching method or a wet etching method, and in the operation 64, the first contact structure 31 and the second contact structure 32 are formed in the openings 73. After the operation 64, the first contact structure 31, the second contact structure 32, the dielectric layer 53, and the interlayer dielectric layer 54 described in FIGS. 1 and 2A to 2D are formed.

The semiconductor structure of the present disclosure and the semiconductor structure formed by the method of the present disclosure include the word line(s) having smaller stress to avoid bending. Therefore, the damage to the word line(s) is prevented from perishing the performance of the semiconductor structure. Moreover, when the semiconductor structure includes more than one word line, the distance between the two adjacent word lines can be smaller without having the bent word lines to cause the electrical short and/or signal interference between the two adjacent word lines. In addition, the method of the present disclosure is easy to implement to save costs.

The present disclosure is described in considerable detail in some embodiments, but other embodiments may also be feasible, so the description of the embodiments in the present disclosure is not intended to limit the scope and spirit of the claims attached. For one skilled in the art, the present disclosure may be modified and changed without deviating from the scope and spirit of the present disclosure. Such modifications and changes are intended to be covered by the present disclosure when they belong to the scope and spirit of the attached claims.

What is claimed is:

1. A semiconductor structure, comprising:
a substrate;
a first word line extending along a first direction on the substrate, wherein the first word line comprises:
a first end portion;
a second end portion; and
a first middle portion between the first end portion and the second end portion, wherein a top surface of the first end portion and a top surface of the second end portion are lower than a top surface of the first middle portion, and a length of the second end portion is larger than a length of the first end portion; and
a first contact structure on the first end portion of the first word line.

2. The semiconductor structure of claim 1, wherein a horizontal distance from a boundary of the first end portion closest to the second end portion to the first contact structure is from 100 nm to 1000 nm.

3. The semiconductor structure of claim 1, wherein the first middle portion comprises a high work function layer and a low work function layer disposed on the high work function layer, a work function of the high work function layer is larger than a work function of the low work function layer, the first end portion is a work function layer having a work function larger than the work function of the low work function layer, and the second end portion is a work function layer having a work function larger than the work function of the low work function layer.

4. The semiconductor structure of claim 1, wherein the first middle portion comprises a metal-containing layer and a silicon-containing conductive layer disposed on the metal-containing layer, the first end portion comprises a metal-containing layer in direct contact with the first contact structure, and the second end portion comprises a metal-containing layer.

5. The semiconductor structure of claim 1, wherein a first top surface of the substrate around the first middle portion is higher than a second top surface of the substrate around the first end portion and a third top surface of the substrate around the second end portion.

6. The semiconductor structure of claim 1, further comprising:
a second word line adjacent to the first word line and extending along the first direction on the substrate, wherein the second word line comprises:
a third end portion adjacent to the first end portion of the first word line;
a fourth end portion adjacent to the second end portion of the first word line; and
a second middle portion between the third end portion and the fourth end portion, wherein a top surface of the third end portion and a top surface of the fourth end portion are lower than a top surface of the second middle portion, and a length of the third end portion is larger than a length of the fourth end portion; and
a second contact structure on the fourth end portion of the second word line.

7. The semiconductor structure of claim 6, wherein a virtual line passes through the first contact structure and a point of the third end portion in a second direction perpendicular to the first direction, and a horizontal distance from a boundary of the third end portion closest to the fourth end portion to the point is from 200 nm to 3000 nm.

8. The semiconductor structure of claim 6, wherein the first word line, the first contact structure, the second word line, and the second contact structure are in a group, the semiconductor structure further comprises groups respectively identical to the group on the substrate, and each one of the groups is aligned with the group.

9. A method of forming a semiconductor structure, comprising:
forming a first word line extending along a first direction on a substrate;
forming a mask on a first middle portion of the first word line and exposing a first end and a second end of the first word line, wherein a length of the second end exposed by the mask is larger than a length of the first end exposed by the mask, and the first middle portion is between the first end and the second end;
etching a portion of the first end and a portion of the second end of the first word line exposed by the mask to form a first end portion and a second end portion of the first word line respectively, wherein a top surface of the first end portion and a top surface of the second end portion are lower than a top surface of the first middle portion; and
forming a first contact structure on the first end portion.

10. The method of claim 9, wherein a length of the second end portion is larger than a length of the first end portion.

11. The method of claim 9, wherein:
the first end comprises a high work function layer and a low work function layer disposed on the high work function layer, and a work function of the high work function layer is larger than a work function of the low work function layer;
when etching the portion of the first end of the first word line exposed by the mask, the portion comprises the low work function layer; and
when forming the first contact structure, the first contact structure is in direct contact with the high work function layer.

12. The method of claim 9, wherein etching the portion of the first end of the first word line exposed by the mask further comprises etching a portion of the substrate around the first end.

13. The method of claim 9, further comprising:
forming a second word line extending along the first direction on the substrate;
forming the mask on a second middle portion of the second word line and exposing a third end and a fourth end of the second word line, wherein a length of the third end exposed by the mask is larger than a length of the fourth end exposed by the mask, the second middle portion is between the third end and the fourth end, and the third end and the fourth end are respectively adjacent to the first end and the second end of the first word line; and
etching a portion of the third end and a portion of the fourth end of the second word line exposed by the mask to form a third end portion and a fourth end portion of the second word line respectively.

14. The method of claim 13, further comprising forming a second contact structure on the fourth end portion.

15. The method of claim 13, wherein the mask has jagged edges along the first direction.
